(19) United States
(12) Patent Application Publication
(10) Pub. No.: US 2015/0165752 A1
(43) Pub. Date: Jun. 18, 2015

(54) METHOD AND DEVICE FOR PERMANENT BONDING OF WAFERS

(71) Applicants: Thomas Plach, Linz (AT); Kurt Hingerl, Wolfern (AT); Markus Wimplinger, Ried im Innkreis (AT); Christoph Flötgen, Pramerdorf (AT)

(72) Inventors: Thomas Plach, Linz (AT); Kurt Hingerl, Wolfern (AT); Markus Wimplinger, Ried im Innkreis (AT); Christoph Flötgen, Pramerdorf (AT)

(73) Assignee: EV Group E. Thallner GmbH, St. Florian am Inn (AT)

(21) Appl. No.: 14/414,795

(22) PCT Filed: Jul. 24, 2012
(86) PCT No.: PCT/EP2012/064545

§ 371 Date: Jan. 14, 2015

(51) Int. Cl. B32B 38/10; B32B 37/00; H01J 37/32

(52) U.S. Cl. CPC B32B 38/10; H01J 37/32036; H01J 37/32339; H01J 37/32532; H01J 37/32798; B32B 37/0046; H01J 2237/334

(57) ABSTRACT

A method for bonding of a first contact area of a first substrate to a second contact area of a second substrate, the second substrate having a least one reaction layer, and a device for carrying out said method. The method comprises: (a) accommodating the substrates between a first electrode and a second electrode, or within a coil, (b) formation of a reservoir on the first contact area by exposing the first contact area to a plasma (c) at least partially filling of the reservoir with a first educt or a first group of educts, (d) contacting the first contact area with the second contact area for formation of a pre-bond interconnection, (e) forming a permanent bond between the first and second contact areas at least partially strengthened by the reaction of the first educt with a second educt which is contained in the reaction layer of the second substrate.

### FIELD OF THE INVENTION

This invention relates to a method for bonding of a first contact area of a first substrate to a second contact area of a second substrate and a device for carrying out said method.

### BACKGROUND OF THE INVENTION

The objective in permanent or irreversible bonding of substrates is to produce an interconnection which is as strong and especially as irreversible as possible, therefore a high bond force, between the two contact areas of the substrates. There are various approaches and production methods for this purpose in the prior art.

The known production methods and the approaches which have been followed to date often lead to results which cannot be reproduced or can be poorly reproduced and which can hardly be applied in particular to altered conditions. In particular, production methods which are used at present often use high temperatures, especially >400° C., in order to ensure reproducible results.

Technical problems such as high energy consumption and a possible destruction of structures which are present on the substrates result from the high temperatures of partially far above 300° C. which have been necessary to date for a high bond force.

Other demands consist in the following:
(a) front-end-of-line compatibility.
   This is defined as the compatibility of the process during the production of the electrically active components. The bonding process must therefore be designed such that active components such as transistors, which are already present on the structure wafers, are neither adversely affected nor damaged during the processing. Compatibility criteria include mainly the purity of certain chemical elements (mainly in CMOS structures) and mechanical loadability, mainly by thermal stresses.
(b) low contamination.
(c) no application of force.
(d) temperature as low as possible, especially for materials with different coefficients of thermal expansion.

The reduction of the bond force leads to more careful treatment of the structure wafer and thus to a reduction of the failure probability by direct mechanical loading.

### SUMMARY OF THE INVENTION

The object of this invention is therefore to devise a method and a device for careful production of a permanent bond with a bond force which is as high as possible at a temperature which is at the same time as low as possible.

This object is achieved with the features of the independent claim(s). Advantageous developments of the invention are given in the dependent claims. All combinations of at least two of the features given in the specification, the claims and/or the figures also fall within the framework of the invention. At the given value ranges, values within the indicated limits will also be considered to be disclosed as boundary values and will be claimed in any combination.

The basic idea of this invention is, using a capacitively coupled plasma or an inductively coupled plasma or a plasma from a remote plasma apparatus, to produce a plasma using which a reservoir for holding a first educt in one substrate is formed, which educt after making contact or producing a temporary bond between the substrates reacts with a second educt which is present in the other substrate, and which thus forms an irreversible or permanent bond between the substrates. Before or after forming the reservoir in a reservoir formation layer on the first contact area, generally cleaning of the substrate or substrates, especially by a flushing step, occurs. This cleaning should generally ensure that there are no particles on the surfaces which would result in unbonded sites. The reservoir and the educt which is contained in the reservoir make it technically possible to induce directly on the contact areas after producing the temporary or reversible bond, in a dedicated manner, a reaction which increases the bonding speed and strengthens the permanent bond (first educt or first group with a second educt or a second group), especially by deformation of at least one of the contact areas by the reaction, preferably the contact area opposite the reservoir. On the opposing second contact area there is a growth layer in which the deformation takes place and the first educt (or the first group) reacts with the second educt (or the second group) which is present in the reaction layer of the second substrate. To accelerate the reaction between the first educt (or the first group) and the second educt (or the second group) it is provided in one advantageous embodiment of the present invention that the growth layer which is located between the reaction layer of the second substrate and the reservoir be thinned before the substrates make contact, since in this way the distance between the reaction partners is reduced in an adjustable manner and at the same time the deformation/formation of the growth layer is promoted. The growth layer is removed at least partially, especially mostly, preferably completely, by the thinning. The growth layer grows again in the reaction of the first educt with the second educt even if it has been completely removed. The thinning of this growth layer could take place especially by means of etching, especially dry etching, polishing, sputtering or reduction of oxides. Preferably a combination of these methods, especially sputtering and oxide reduction, is conceivable.

There can be means for inhibiting the growth of the growth layer before the contact areas make contact, especially by passivation of the reaction layer of the second substrate, preferably by exposure to N₂, forming gas or an inert atmosphere or under a vacuum or by amorphization. In this connection, treatment with plasma which contains forming gas, especially consists largely of forming gas, has proven especially suitable. Here forming gas is defined as gases which contain at least 2%, better 4%, ideally 10% or 15% hydrogen. The remaining portion of the mixture consists of an inert gas, such as for example nitrogen or argon.

When using forming gas it is possible in particular to thin the oxide layer by a process which is based on sputtering and oxide reduction.

Alternatively or in addition to this measure, it is advantageous to minimize the time between the thinning and the contact-making, especially <2 hours, preferably <30 minutes, even more preferably <15 minutes, ideally <5 minutes. Thus the oxide growth which takes place after thinning can be minimized.

The diffusion rate of the educts through the growth layer is increased by the growth layer which has been thinned and which is thus very thin at least at the beginning of the formation of the permanent bond or at the start of the reaction. This leads to a shorter transport time of the educts at the same temperature.

For the prebonding step, for producing a temporary or reversible bond between the substrates, there are various possibilities with the objective of producing a weak interaction between the contact areas of the substrates. The prebond strengths are below the permanent bond strengths, at least by a factor of 2 to 3, especially by a factor of 5, preferably by a factor of 15, still more preferably by a factor of 25. As guideline values the prebond strengths of pure, nonactivated, hydrophilized silicon with roughly 100 mJ/m² and of pure, plasma-activated hydrophilized silicon with roughly 200-300 mJ/m² are mentioned. The prebonds between the molecule-wetted substrates arise mainly due to the van der Waals interactions between the molecules of the different wafer sides. Accordingly, mainly molecules with permanent dipole moments are suitable for enabling prebonds between wafers. The following chemical compounds are mentioned as interconnect agents by way of example, but not limited thereto

water,

thiols,

AP3000,

silanes, and/or

silanols.

Suitable substrates are those whose material is able to react as an educt with another supplied educt to form a product with a higher molar volume, as a result of which the formation of a growth layer on the substrate is caused. The following combinations are especially advantageous, to the left of the arrow the educt being named and to the right of the arrow, the product/products, without the supplied educt or byproducts which react with the educt being named in particular:

Si→SiO₂, Si₃N₄, SiNₓO_{y}

Ge→GeO₂, Ge₃N₄

α-Sn→SnO₂

B→B₂O₃, BN

Se→SeO₂

Te→TeO₂, TeO₃

Mg→MgO, Mg₃N₂

Al→Al₂O₃, AlN

Ti→TiO₂, TiN

V→V₂O₅

Mn→MnO, MnO₂, Mn₂O₃, Mn₂O₇, Mn₃O₄

Fe→FeO, Fe₂O₃, Fe₃O₄

Co→CoO, Co₃O₄,

Ni→NiO, Ni₂O₃

Cu→CuO, Cu₂O, Cu₃N

Zn→ZnO

Cr→CrN, Cr₂₃C₆, Cr₃C, Cr₇C₃, Cr₃C₂

Mo→Mo₃C₂

Ti→TiC

Nb→Nb₄C₃

Ta→Ta₄C₃

Zr→ZrC

Hf→HfC

V→V₄C₃, VC

W→W₂C, WC

Fe→Fe₃C, Fe₇C₃, Fe₂C.

The following mixed forms of semiconductors are moreover conceivable as substrates:
III-V: GaP, GaAs, InP, InSb, InAs, GaSb, GaN, AlN, InN, AlₓGa₁₋ₓAs, InₓGa₁₋ₓN

IV-IV: SiC, SiGe,

III-VI: InAlP.

nonlinear optics: LiNbO₃, LiTaO₃, KDP (KH₂PO₄)

solar cells: CdS, CdSe, CdTe, CuInSe₂, CuInGaSe₂, CuInS₂, CuInGaS₂

conductive oxides: In₂₋ₓSnxO_{3-y}

On at least one of the wafers and directly on the respective contact area there is the reservoir (or reservoirs) in which a certain amount of at least one of the supplied educts for the volume expansion reaction can be stored. Educts can therefore be for example O₂, O₃, H₂O, N₂, NH₃, H₂O₂, etc. Due to the expansion, especially dictated by oxide growth, based on the tendency of the reaction partners to reduce system energy, possible gaps, pores, and cavities between the contact areas are minimized and the bond force is increased accordingly by narrowing the distances between the substrates in these regions. In the best possible case the existing gaps, pores and cavities are completely closed so that the entire bonding area increases and thus the bond force rises accordingly.

The contact areas conventionally show a roughness with a quadratic roughness (R_{q}) of 0.2 nm. This corresponds to peak-to-peak values of the surfaces in the range of 1 nm. These empirical values were determined with atomic force microscopy (AFM).

The reaction is suitable for allowing the growth layer to grow by 0.1 to 0.3 nm for a conventional wafer surface of a circular wafer with a diameter from 200 to 300 mm with 1 monolayer (ML) of water.

It is therefore provided in particular that at least 2 ML, preferably at least 5 ML, even more preferably at least 10 ML of fluid, especially water, be stored in the reservoir.

The formation of the reservoir by exposure to plasma is especially preferable, since plasma exposure moreover causes smoothing of the contact area and hydrophilization as synergy effects. The surface is smoothed by plasma activation predominantly by a viscous flow of the material of the reservoir formation layer and optionally of the reaction layer. The increase of the hydrophilicity takes place especially by the increase of the silicon hydroxyl compounds, preferably by cracking of Si—O compounds which are present on the surface, such as Si—O—Si, especially according to the following reaction:

Si—O—Si+H₂O [symbol] 2SiOH

Another side effect, especially as a result of the aforementioned effects, consists in that the prebond strength is improved especially by a factor of 2 to 3.

The reservoir in the reservoir formation layer on the first contact area of the first substrate (and optionally of a reservoir formation layer on the second contact area of the second substrate) is formed for example by plasma activation of the first substrate which has been coated with a thermal oxide. The plasma activation is carried out in a vacuum chamber in order to be able to set the conditions necessary for the plasma. For the plasma discharge, N₂ gas, O₂ gas or argon gas with ion energies in the range from 0 to 2000 eV is used, as a result of which a reservoir is produced with a depth of up to 20 nm, preferably up to 15 nm, more preferably up to 10 nm, most preferably up to 5 nm, of the treated surface, in this case the first contact area.

By setting a certain pressure in the vacuum chamber the average free path length for the plasma ions can be conceivably influenced or set.

Reproducible results in the production of the reservoir on the contact area/areas is possible by the inventive use of two different frequencies on the opposing electrodes to produce the plasma, which electrodes accelerate the plasma ions especially with application of an alternating current or an ac voltage, and/or by the use of an inductively coupled plasma source and/or remote plasma.

In the case of capacitive coupling it is advantageous if the electrodes are located within the plasma chamber.

Here optimum exposure of the contact areas and thus production of a reservoir which is defined exactly, especially in terms of volume and/or depth, are enabled by setting the parameters (different) the frequencies of the electrodes, the amplitudes, especially, preferably exclusively, the bias voltage applied on the second electrode and the chamber pressure.

The execution of the plasma activation apparatus as a capacitively coupled, double frequency plasma apparatus advantageously enables a separate setting of the ion density and the acceleration of the ions onto the wafer surface. Thus attainable process results can be set within a wide window and can be optimally matched to the demands of the application.

The bias voltage, especially in the form of a base voltage of the second, especially lower electrode, is used to influence the impact (speed) of the electrodes on the contact area of the substrate which is held on the second electrode, especially to attenuate or accelerate it.

In particular, the pore density distribution in the reservoir becomes adjustable by the aforementioned parameters, especially advantageous embodiments being described below.

In an inductively coupled plasma source, corresponding analogy considerations about the ac voltage of the capacitive coupling to alternating currents which are used to generate a magnetic field can be adopted. It is conceivable manipulate the plasma of the inductively coupled plasma source by an alternating current or alternating magnetic field of varied strength and/or frequency such that the plasma has the corresponding properties.

In a remote plasma, the plasma which is to actually be used is generated in an external source and is introduced into the sample space. In particular, components of this plasma, especially ions, are transported into the sample space. The passage of the plasma from the source space into the substrate space can be ensured by different elements such as locks, accelerators, magnetic and/or electrical lenses, diaphragms, etc. All considerations which apply to capacitively and/or inductively coupled plasma with respect to frequencies and/or strengths of the electrical and/or magnetic fields will apply to all elements which ensure the production and/or passage of the plasma from the source space into the substrate space. For example, it would be conceivable for the plasma to be produced by capacitive or inductive coupling by the parameters in the source space and afterwards for the aforementioned elements to penetrate into the substrate space.

Any particle type, atoms and/or molecules which are suitable for producing the reservoir can be used. Preferably those atoms and/or molecules are used which the reservoir produces with the required properties. The relevant properties are mainly the pore size, the pore distribution and the pore density. Alternatively, gas mixtures such as for example air or forming gas consisting of 95% Ar and 5% H₂ can be used. Depending on the gas used, in the reservoir during the plasma treatment among others the following ions are present: N+, N₂+, O+, O₂+, Ar+. The first educt can be accommodated in the unoccupied free space of the reservoir/reservoirs. The reservoir formation layer and accordingly the reservoir can extend into the reaction layer.

Advantageously there are different types of plasma species which can react with the reaction layer and which consist at least partially, preferably mostly of the first educt. To the extent the second educt is Si/Si, an Oₓ plasma species would be advantageous.

The reservoir is formed based on the following considerations: The pore size is smaller than 10 nm, preferably smaller than 5 nm, more preferably smaller than 1 nm, even more preferably smaller than 0.5 mm, most preferably smaller than 0.2 nm.

The pore density is preferably directly proportional to the density of the particles which produce the pores by striking action, most preferably it can even be varied by the partial pressure of the striking species, and depending on the treatment time and the parameters, especially of the plasma system used.

The pore distribution preferably has at least one region of greatest pore concentration under the surface by variation of the parameters of several such regions which are superimposed into a preferably plateau-shaped region (see FIG. 8). The pore distribution decreases toward zero with increasing thickness. The region near the surface during bombardment has a pore density which is almost identical to the pore density near the surface. After the end of plasma treatment the pore density on the surface can be reduced as a result of stress relaxation mechanisms. The pore distribution in the thickness direction with respect to the surface has one steep flank and with respect to the bulk a rather flatter, but continuously decreasing flank (see FIG. 8).

For the pore size, the pore distribution and pore density, similar considerations apply to all methods not produced with plasma.

The reservoir can be designed by controlled use and combination of process parameters. FIG. 8 shows a representation of the concentration of injected nitrogen atoms by plasma as a function of the penetration depth into a silicon oxide layer. It was possible to produce two profiles by variation of the physical parameters. The first profile 11 was produced by more highly accelerated atoms more deeply in the silicon oxide, conversely the profile 12 was produced after altering the process parameters in a lower density. The superposition of the two profiles yields a sum curve 13 which is characteristic for the reservoir. The relationship between the concentration of the injected atom and/or molecule species is evident. Higher concentrations designate regions with a higher defect structure, therefore more space to accommodate the subsequent educt. A continuous change of the process parameters which is controlled especially in a dedicated manner during the plasma activation makes it possible to achieve a reservoir with a distribution of the added ions over depth, which distribution is as uniform as possible.

Alternatively to a reservoir which has been produced by plasma, the use of a TEOS (tetraethylorthosilicate) oxide layer on at least one of the substrates, at least the first substrate, is conceivable as a reservoir. This oxide is generally less dense than thermal oxide, for which reason compaction is advantageous. Compaction takes place by heat treatment with the objective of setting a defined porosity of the reservoir.

According to one embodiment of the invention, the filling of the reservoir can take place especially advantageously at the same time with the formation of the reservoir by the reservoir being applied as a coating to the first substrate, the coating already encompassing the first educt.

The reservoir is conceivable as a porous layer with a porosity in the nanometer range or as a layer which has channels with a channel thickness smaller than 10 nm, more preferably smaller than 5 nm, even more preferably smaller than 2 nm, most preferably smaller than 1 nm, most preferably of all smaller than 0.5 nm.

For the step of filling of the reservoir with a first educt or a first group of educts, the following embodiments, also in combination, are conceivable:
exposing the reservoir to the ambient atmosphere,
flushing with especially deionized water,
flushing with a fluid which contains the educt or which consists of it, especially H₂O, H₂O₂, NH₄OH
exposing the reservoir to any gas atmosphere, especially atomic gas, molecular gas, gas mixtures,
exposing the reservoir to a water vapor-containing or hydrogen peroxide vapor-containing atmosphere and
depositing a reservoir which has already been filled with the educt as a reservoir formation layer on the first substrate.

The following compounds are possible as educts: Oₓ⁺, O₂, O₃, N₂, NH₃, H₂O, H₂O₂, and/or NH₄OH.

The use of the above cited hydrogen peroxide vapor is regarded as the preferred version, in addition to using water. Hydrogen peroxide furthermore has the advantage of having a greater oxygen to hydrogen ratio. Furthermore, hydrogen peroxide dissociates above certain temperatures and/or via the use of high frequency fields in the MHz range into hydrogen and oxygen.

On the other hand, H₂O offers the advantage of having a small molecule size. The size of the H₂O molecular is even smaller than that of the O₂ molecule, with which H₂O offers the advantage of being able to be more easily intercalated in the pores and being able to diffuse more easily through the growth layer.

Mainly when using materials with different coefficients of thermal expansion the use of methods for dissociation of the aforementioned species which do not cause any noteworthy temperature increase or at best a local/specific temperature increase is advantageous. In particular there is microwave irradiation which at least promotes, preferably causes the dissociation.

According to one advantageous embodiment of the invention it is provided that the formation of the growth layer and strengthening of the irreversible bond take place by diffusion of the first educt into the reaction layer.

According to another advantageous embodiment of the invention it is provided that the formation of the irreversible bond takes place at a temperature of typically less than 300° C., advantageously less than 200° C., more preferably less than 150° C., even more preferably less than 100° C., most preferably at room temperature, especially during a maximum 12 days, more preferably a maximum 1 day, even more preferably a maximum 1 hour, most preferably a maximum 15 minutes. Another advantageous heat treatment method is dielectric heating by microwaves.

Here it is especially advantageous if the irreversible bond has a bond strength of greater than 1.5 J/m², especially greater than 2 J/m², preferably greater than 2.5 J/m².

The bond strength can be increased especially advantageously in that during the reaction, a product with a greater molar volume than the molar volume of the second educt is formed in the reaction layer. In this way growth on the second substrate is effected, as a result of which gaps between the contact areas can be closed by the chemical reaction. As a result, the distance between the contact areas, therefore the average distance, is reduced, and dead spaces are minimized.

To the extent the formation of the reservoir takes place by plasma activation, especially with an activation frequency between 10 kHz and 20000 kHz, preferably between 10 kHz and 5000 kHz, even more preferably between 10 kHz and 1000 kHz, most preferably between 10 kHz and 600 kHz and/or a power density between 0.075 and 0.2 watt/cm² and/or with pressurization with a pressure between 0.1 and 0.6 mbar, additional effects such as smoothing of the contact area and also a clearly increased hydrophilicity of the contact area are caused.

Alternatively the formation of the reservoir can take place by using a tetraethoxysilane oxide layer which has been compacted in an especially controlled manner to a certain porosity as the reservoir formation layer.

According to another advantageous embodiment of the invention it is provided that the reservoir formation layer consists largely, especially essentially completely of an especially amorphous silicon dioxide, especially a silicon dioxide which has been produced by thermal oxidation, and the reaction layer consists of an oxidizable material, especially predominantly, preferably essentially completely, of Si, Ge, InP, GaP or GaN (or another material mentioned alternatively above). An especially stable reaction which especially effectively closes the existing gaps is enabled by oxidation.

Here it is provided that between the second contact area and the reaction layer there is a growth layer, especially predominantly of native silicon dioxide (or another material mentioned alternatively above). The growth layer is subject to growth caused by the reaction. The growth takes place proceeding from the transition Si—SiO2 (7) by re-formation of amorphous SiO2 and the deformation caused thereby, especially bulging, of the growth layer, especially on the interface to the reaction layer, and especially in regions of gaps between the first and the second contact area. This causes a reduction of the distance or a reduction of the dead space between the two contact areas, as a result of which the bond strength between the two substrates is increased. A temperature between 200 and 400° C., preferably roughly 200° C. and 150° C., more preferably a temperature between 150° C. and 100° C., most preferably a temperature between 100° C. and room temperature, is especially advantageous. The growth layer can be divided into several growth regions. The growth layer can at the same time be a reservoir formation layer of the second substrate in which another reservoir which accelerates the reaction is formed.

Here it is especially advantageous if the growth layer has an average thickness A between 0.1 nm and 5 nm prior to formation of the irreversible bond. The thinner the growth layer, the more quickly and easily the reaction takes place between the first and the second educt through the growth layer, especially by diffusion of the first educt through the growth layer to the reaction layer. The diffusion rate of the educts through the growth layer is increased by the growth layer which has been thinned and thus is very thin at least at the beginning of the formation of the permanent bond or at the start of the reaction. This leads to a shorter transport time of the educts at the same temperature.

Here the thinning plays a decisive part since the reaction can be further accelerated and/or the temperature can be further reduced by it. Thinning can be done especially by etching, preferably in a moist atmosphere, still more preferably in-situ. Alternatively the thinning takes place especially by dry etching, preferably in-situ. Here in-situ means performance in the same chamber in which at least one previous and/or one following step is/are carried out. A further apparatus arrangement which falls under the in-situ concept used here is an apparatus in which the transport of the substrates takes place between individual process chambers in an atmosphere which can be adjusted in a controlled manner, for example using inert gases, but especially in a vacuum environment. Wet etching takes place with chemicals in the vapor phase, while dry etching takes place with chemicals in the liquid state. To the extent the growth layer consists of silicon dioxide, etching with hydrofluoric acid or diluted hydrofluoric acid can be done. To the extent the growth layer consists of pure Si, etching can be done with KOH.

According to one embodiment of the invention it is advantageously provided that the formation of the reservoir is carried out in a vacuum. Thus contamination of the reservoir with unwanted materials or compounds can be avoided.

In another embodiment of the invention, it is advantageously provided that filling of the reservoir takes place by one or more of the steps cited below:
exposing the first contact area to the atmosphere, for filling the reservoir with atmospheric humidity and/or oxygen contained in the air,
exposing the first contact area to a fluid consisting especially predominantly, preferably almost completely, of especially deionized H₂O and/or H₂O₂,
exposing the first contact area to N₂ gas and/or O₂ gas and/or Ar gas and/or forming gas, especially consisting of 95% Ar and 5% H₂, especially with an ion energy in the range from 0 to 2000 eV,
vapor deposition for filling the reservoir with any already named educt.

It is especially effective for the process sequence if the reservoir is formed preferably in a thickness R between 0.1 nm and 25 nm, more preferably between 0.1 nm and 15 nm, even more preferably between 0.1 nm and 10 nm, most preferably between 0.1 nm and 5 nm. Furthermore, according to one embodiment of the invention it is advantageous if the average distance B between the reservoir and the reaction layer immediately before formation of the irreversible bond is between 0.1 nm and 15 nm, especially between 0.5 nm and 5 nm, preferably between 0.5 nm and 3 nm. The distance B is influenced or produced by the thinning.

A device for executing the method is made with a chamber for forming the reservoir, a chamber provided especially separately from it for filling the reservoir, and an especially separately provided chamber for forming the prebond, all of which chambers are connected directly to one another via a vacuum system.

In another embodiment the filling of the reservoir can also take place directly via the atmosphere, therefore either in a chamber which can be opened to the atmosphere or simply on a structure which does not have jacketing, but can handle the wafer semiautomatically and/or completely automatically.

Other advantages, features and details of the invention will become apparent from the following description of preferred exemplary embodiments and using the drawings.

### BRIEF DESCRIPTION OF THE DRAWINGS

FIG. 1a shows a first step of the method immediately after the first substrate makes contact with the second substrate,

FIG. 1b shows an alternative first step of the method immediately after the first substrate makes contact with the second substrate,

FIG. 2 shows a step of the method which takes place prior to contact-making, specifically the thinning of the second substrate,

FIGS. 3a and 3b show other steps of the method for forming a higher bond strength,

FIG. 4 shows another step of the method which follows the steps according to FIG. 1a or 1b, FIG. 2 and FIGS. 3a and 3b, with substrate contact areas which are in contact,

FIG. 5 shows a step for formation of an irreversible/permanent bond between the substrates,

FIG. 6 shows an enlargement of the chemical/physical processes which proceed on the two contact areas during the steps according to FIG. 4 and FIG. 5,

FIG. 7 shows a further enlargement of the chemical/physical processes which proceed on the interface between the two contact areas during the steps according to FIG. 4 and FIG. 5,

FIG. 8 shows a diagram of the production of the reservoir,

FIG. 9 shows a schematic of a capacitive plasma chamber which can be exposed to a vacuum,

FIG. 10 shows a schematic of an inductive plasma chamber which can be exposed to a vacuum,

FIG. 11 shows a schematic of a remote plasma chamber which can be exposed to a vacuum and

FIG. 12 shows a diagram on frequency behaviors of the frequencies of the two electrodes.

The same or equivalent features are identified with the same reference numbers in the figures.

### DETAILED DESCRIPTION OF THE INVENTION

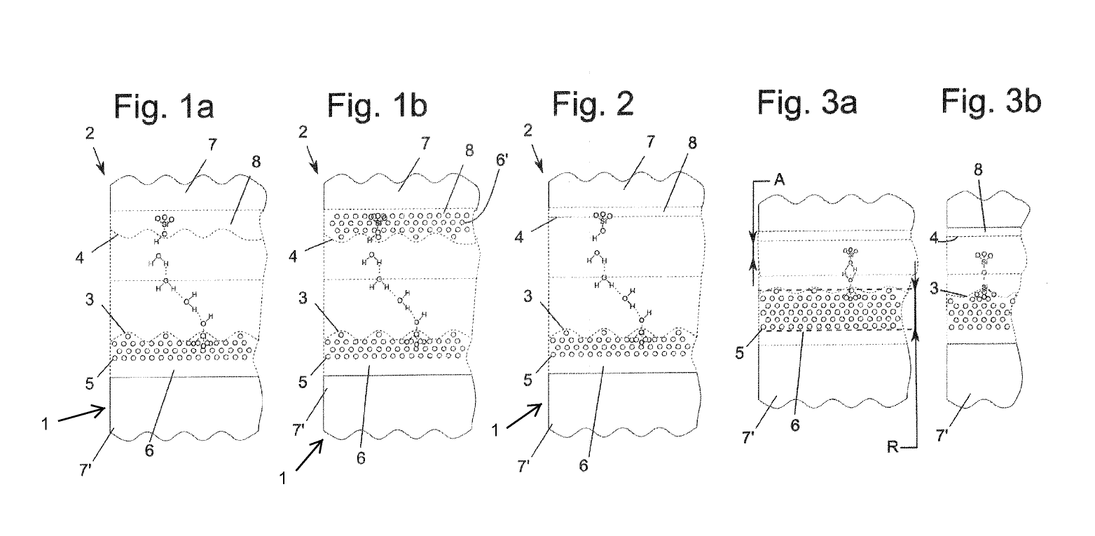

In the situation shown in FIG. 1, only one extract of the chemical reactions which proceed during or immediately after the prebond step between a first contact area 3 of a first substrate 1 and a second contact area 4 of a second substrate 2 is shown. The surfaces are terminated with polar OH groups and are accordingly hydrophilic. The first substrate 1 and the second substrate 2 are held by the force of attraction of the hydrogen bridges between the OH groups present on the surface and the H₂O molecules and also between the H₂O molecules alone. The hydrophilicity of at least the first substrate 1 has been increased by plasma treatment in a preceding step.

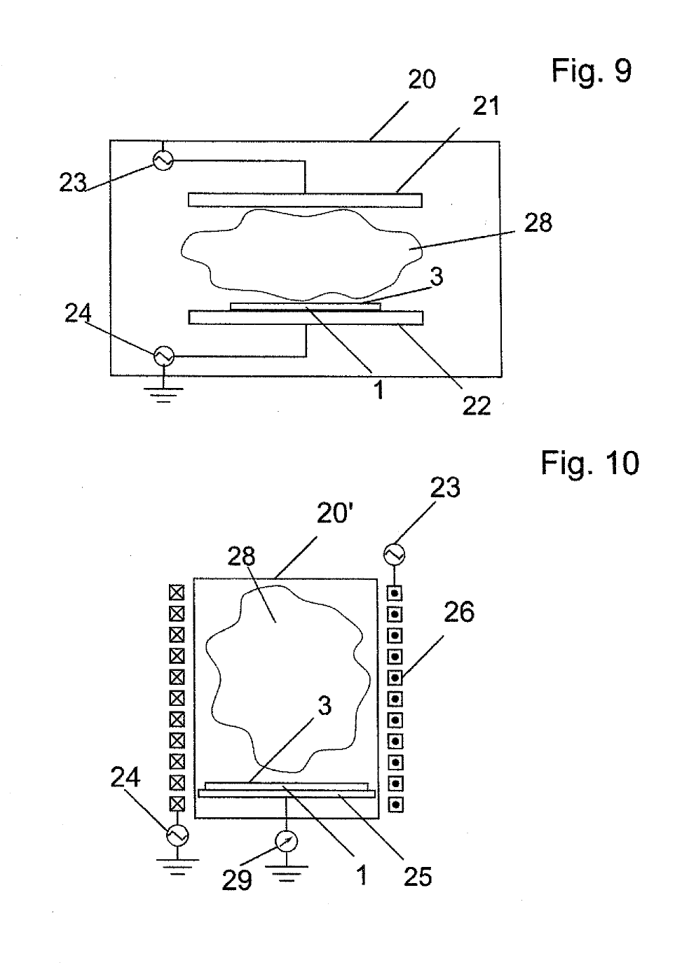

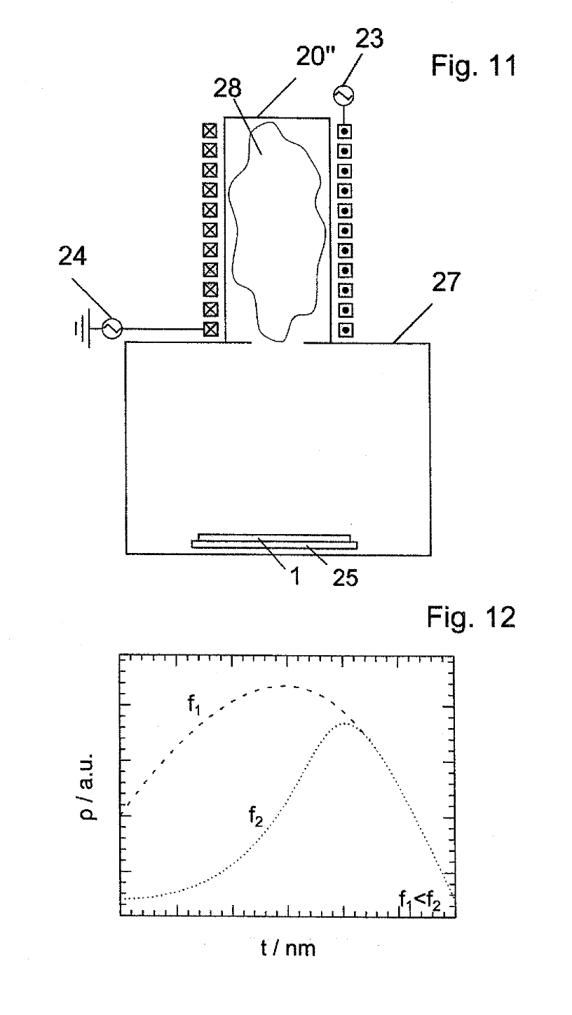

Plasma treatment takes place in a plasma chamber 20 which can be exposed to plasma and a vacuum and/or a defined gas atmosphere according to FIG. 9. To be exposed to a vacuum and/or a defined gas atmosphere means that pressures below 1 mbar can be set and controlled. In the exemplary embodiment described here the gas is N₂ at a pressure of 0.3 mbar. In the embodiments of the capacitive and inductive coupling, the plasma chamber 20 and substrate chamber are identical. In the embodiment of the remote plasma according to FIG. 11, the plasma chamber 20″ is separate from a substrate chamber 27 which accommodates the substrate.

The capacitive plasma chamber 20 shown in FIG. 9 has a first electrode 21 (which is located at the top or is the upper electrode) for ionization of the gas volume which is caused by the ac voltage on the first electrode 21 with a frequency f₂₁ between 0.001 kHz and 100000 kHz, preferably between 0.01 kHz and 10000 kHz, even more preferably between 0.1 kHz and 1000 kHz, most preferably between 250 and 550 kHz and an amplitude between 1 V and 1000 V, especially between 100 V and 800 V, preferably between 200 V and 600 V, even more preferably between 300 V and 500 V. One important factor is the average free path length which is defined by the above described vacuum.

There is another second electrode 22 (which is located below or is the lower electrode) which is opposite the first electrode 21 not only for exposure of the first contact area 3, which exposure is coupled to the frequency of the first electrode 21, but in addition has a bias voltage as the base voltage which accelerates or attenuates the impact of the plasma ions. The bias voltage is generally an ac voltage or a dc voltage. Advantageously a de voltage is used which during the plasma activation process can be dynamically changed over a curve defined in a stored/given shape (formula). The second electrode 22 in the embodiment shown here works with a frequency f₂₂ between 0.001 kHz and 100000 kHz, preferably between 0.01 kHz and 10000 kHz, even more preferably between 0.1 kHz and 1000 kHz, most preferably from 15 kHz to 55 kHz and an amplitude between 1 V and 1000 V, especially between 100 V and 800 V, preferably between 200 V and 600 V, even more preferably between 300 V and 500 V. This second ac voltage also leads to a variation of the ion energy of the ions striking the contact area 3, with which a uniform depth distribution of the ions can be achieved.

The second electrode 21 is used in addition as a receiver for the first substrate 1 with its receiving side facing away from the first contact area 3. Thus the first substrate 1 (without the second substrate 2) is located between the first electrode 21 and the second electrode 22. Holders for the electrodes 21, 22 are not shown.

Each electrode 21, 22 is preferably connected to its own power supply in the form of a generator 23 for the first electrode 21 and a second generator 24 which can be controlled separately therefrom for the second electrode 22. The first generator 23 works especially between 1 watt and 100000 watts, preferably between 25 watts and 10000 watts, more preferably between 30 watts and 1000 watts, most preferably between 50 watts and 200 watts, most preferably of all between 70 watts and 130 watts. The second generator 24 likewise delivers a power between 1 watt and 100000 watts, preferably between 25 watts and 10000 watts, more preferably between 30 watts and 1000 watts, most preferably between 50 watts and 200 watts, most preferably of all between 70 watts and 130 watts.

An inductive plasma chamber 20′ according to FIG. 10 has a coil 26 which surrounds it and through which a current with the amplitude flows. The substrate 1 rests on a sample holder 25. In one preferred embodiment the plasma chamber 20′ has exactly two generators 23 and 24.

The inductive plasma chamber 20′ has a first current generator 23 on one side of the coil 26. The current flowing through the coil 26, generated by the first generator 23, has a frequency f₂₁ between 0.001 kHz and 100000 kHz, preferably between 0.01 kHz and 10000 kHz, even more preferably between 0.1 kHz and 1000 kHz, most preferably exactly 400 kHz and an amplitude between 0.001 A and 10000 A, preferably between 0.01 A and 1000 A, more preferably between 0.1 A and 100 A, most preferably between 1 A and 10 A.

Preferably the coil 26 or the plasma chamber 20′ has a second current generator 24. The second current generator 24 has a frequency f₂₂ between 0.001 kHz and 100000 kHz, preferably between 0.01 kHz and 10000 kHz, even more preferably between 0.1 kHz and 1000 kHz, most preferably exactly 400 kHz and an amplitude between 0.001 A and 10000 A, preferably between 0.01 A and 1000 A, more preferably between 0.1 A and 100 A, most preferably between 1 A and 10 A.

In another embodiment according to FIG. 11 the plasma to be produced is produced in a (remote) plasma chamber 20″. All disclosed parameters for the capacitively and/or inductively coupled plasma apply analogously.

FIG. 12 schematically shows the pore density of the plasma which has been produced as a function of the depth for two different frequencies. It is evident that the density profile can be adjusted in a dedicated manner by changing the frequency.

It is especially advantageous, according to the alternative embodiment, to additionally subject the second substrate 2 or the second contact area 4 to plasma treatment, especially simultaneously with the plasma treatment of the first substrate 1.

A reservoir 5 in a reservoir formation layer 6 consisting of thermal silicon dioxide as well as in the alternative embodiment according to FIG. 1b a second opposing reservoir 5′ in the reservoir formation layer 6′ has been formed by plasma treatment. Under the reservoir formation layers 6, 6′, reactions layers 7, 7 which contain a second educt or a second group of educts directly adjoin one another. Plasma treatment with N₂ ions with the aforementioned ion energy yields an average thickness R of the reservoir 5 of roughly 15 nm, the ions forming channels or pores in the reservoir formation layer 6.

Between the reservoir formation layer 6 and the reaction layer 7 there is a growth layer 8 on the second substrate 2 which can be at the same time at least partially the reservoir formation layer 6′. Accordingly there can additionally be another growth layer between the reservoir formation layer 6′ and the reaction layer 7′.

Likewise the reservoir 5 (and optionally the reservoir 5) is filled at least largely with H₂O as the first educt prior to the step shown in FIG. 1 and after plasma treatment. Reduced species of the ions present in the plasma process can also be located in the reservoir, especially O₂, N₂, H₂, Ar.

Before or after the formation of the reservoir/reservoirs 5, 5′, in any case prior to contact-making of the substrates 1, 2, the growth layer 8 (and optionally the other growth layer) is thinned by etching (here after the formation of the reservoir 5, see FIG. 2). In this way the average distance B between the second contact area 4 and the reaction layer 7 is reduced. At the same time the second contact area 4 advantageously becomes more planar.

The contact areas 3, 4 still have a relatively wide distance, especially dictated by the water which is present between the contact areas 3, 4, after making contact in the stage shown in FIG. 1a or 1b. Accordingly the existing bond strength is relatively low and is roughly between 100 mJ/cm² and 300 mJ/cm², especially more than 200 mJ/cm². In this connection the prior plasma activation plays a decisive part, especially due to the increased hydrophilicity of the plasma-activated first contact area 3 and a smoothing effect which is caused by the plasma activation.

The process which is shown in FIG. 1 and which is called prebond can preferably proceed at the ambient temperature or a maximum 50° C. FIGS. 3a and 3b show a hydrophilic bond, the Si—O—Si bridge arising with splitting of water by —OH terminated surfaces. The processes in FIGS. 3a and 3b last roughly 300 h at room temperature. At 50° C. roughly 60 h. The state in FIG. 3b occurs at the indicated temperatures without producing the reservoir 5 (or reservoirs 5, 5).

Between the contact areas 3, 4 H₂O molecules are formed and provide at least partially for further filling in the reservoir 5 to the extent there is still free space. The other H₂O molecules are removed. In the step according to FIG. 1 roughly 3 to 5 individual layers of OH groups or H₂O are present and 1 to 3 monolayers of H₂O are removed or accommodated in the reservoir 5 from the step according to FIG. 1 to the step according to FIG. 3a.

In the step shown in FIG. 3a the hydrogen bridge bonds are now formed directly between siloxane groups, as a result of which a stronger bond force arises. This draws the contact areas 3, 4 more strongly to one another and reduces the distance between the contact areas 3, 4. Accordingly there are only 1 to 2 individual layers of OH groups between the contact areas 3, 4.

In the step shown in FIG. 3b, in turn with deposition of H₂O molecules according to the reaction which has been inserted below, covalent compounds in the form of silanol groups are now formed between the contact areas 3, 4 which lead to a much stronger bond force and require less space, so that the distance between the contact areas 3, 4 is further reduced until finally the minimum distance shown in FIG. 3 is reached as a result of the contact areas 3, 4 directly meeting one another:

Si—OH+HO—Si [symbol] Si—O—Si+H₂O

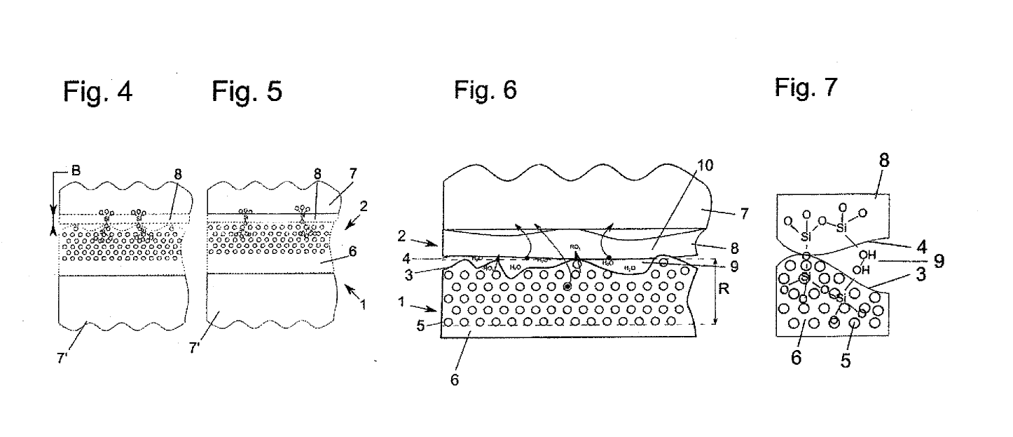

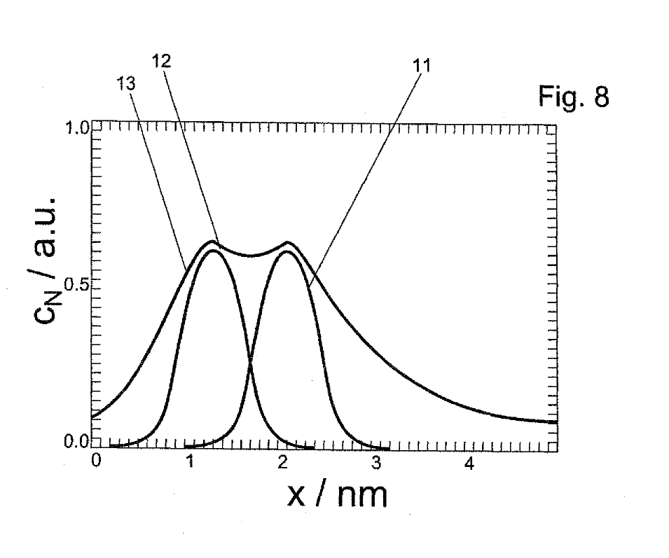

Up to stage 3, especially due to the formation of the reservoir 5 (and optionally of the additional reservoir 5′), it is not necessary to unduly increase the temperature, rather to allow it to proceed even at room temperature. In this way an especially careful progression of the process steps according to FIG. 1a or 1b to FIG. 4 is possible.

In the method step shown in FIG. 5, the temperature is preferably increased to a maximum 500° C., more preferably to a maximum 300° C., even more preferably to a maximum 200° C., most preferably to a maximum 100° C., most preferably of all not above room temperature in order to form an irreversible or permanent bond between the first and the second contact area. These temperatures which are relatively low, in contrast to the prior art, are only possible because the reservoir 5 (and optionally in addition the reservoir 5) encompasses the first educt for the reaction shown in FIGS. 6 and 7:

Si+2H₂O→SiO₂+2H₂

By increasing the molar volume and diffusion of the H₂O molecules, especially on the interface between the reservoir formation layer 6′ and the reaction layer 7 (and optionally in addition on the interface between the reservoir formation layer 6 and the reaction layer 7′) a volume in the form of a growth layer 8 grows, due to the objective of minimizing the free Gibb's enthalpy intensified growth taking place in regions in which gaps 9 are present between the contact areas 3, 4. The gaps 9 are closed by the increase in the volume of the growth layer 8. More specifically:

At the aforementioned slightly increased temperatures, H₂O molecules diffuse as the first educt from the reservoir 5 (or the reservoirs 5, 5) to the reaction layer 7 (and optionally 7′). This diffusion can take place either via a direct contact of the reservoir formation layer 6, 6′ which has been formed as oxide layers with the respective reaction layer 7, 7′ (or growth layer 8) or via a gap 9 or from a gap 9 which is present between the oxide layers. There, silicon dioxide, therefore a chemical compound with a greater molar volume than pure silicon, is formed as a reaction product 10 of the aforementioned reaction from the reaction layer 7. The silicon dioxide grows on the interface of the reaction layer 7 with the growth layer 8 and/or the reservoir formation layer 6, 6′ and thus shapes the growth layer 8 which has been formed especially as native oxide in the direction of the gaps 9. Here H₂O molecules from the reservoir are also required.

Due to the existence of the gaps which are in the nanometer range, there is the possibility of bulging of the growth layer 8, as a result of which stresses on the contact areas 3, 4 can be reduced. In this way the distance between the contact areas 3, 4 is reduced, as a result of which the active contact area and thus the bond strength are further increased. The weld connection which has arisen in this way, which closes all pores, and which forms over the entire wafer, in contrast to the products in the prior art which are partially not welded, fundamentally contributes to increasing the bond force. The type of bond between the two amorphous silicon oxide surfaces which are welded to one another is a mixed form of a covalent and ionic portion.

The aforementioned reaction of the first educt (H₂O) with the second educt (Si) takes place in the reaction layer 7 especially quickly or at temperatures as low as possible to the extent an average distance B between the first contact area 3 and the reaction layer 7 is as small as possible.

Therefore the pretreatment of the first substrate 1 and the selection/pretreatment of the second substrate 2 which consists of a reaction layer 7 of silicon and a native oxide layer as thin as possible as a growth layer 8 are decisive. A native oxide layer as thin as possible is provided for two reasons. The growth layer 8 is very thin, especially due to thinning provided, so that it can bulge through the newly formed reaction product 10 on the reaction layer 7 toward the reservoir formation layer 6 of the opposite substrate 1, which reservoir formation layer is made as an oxide layer, predominantly in regions of the nanogaps 9. Furthermore, diffusion paths as short as possible are desired in order to achieve the desired effect as quickly as possible and at a temperature as low as possible. The first substrate 1 likewise consists of a silicon layer and an oxide layer produced on it as a reservoir formation layer 6 in which a reservoir 5 is formed at least partially or completely.

The reservoir 5 (or the reservoirs 5, 5′) is filled at least with the amount of the first educt which is necessary to close the nanogaps 9 so that an optimum growth of the growth layer 8 can take place to close the nanogaps 9 in a time as short as possible and/or at a temperature as low as possible.

### REFERENCE NUMBER LIST

1 first substrate
2 second substrate
3 first contact area
4 second contact area
5, 5′ reservoir
6, 6′ reservoir formation layer
7, 7 reaction layer
8 growth layer
9 nanogaps
10 reaction product
11 first profile
12 second profile
13 sum curve
20, 20′, 20″plasma chamber
21 first electrode
22 second electrode
23 first generator
24 second generator
25 substrate holder
26 coil
27 substrate chamber for remote plasma
28 induced plasma
29 dc voltage source
A average thickness
B average distance
R average thickness
f₂₁ first frequency
f₂₂ second frequency

1. A method for bonding of a first contact area of a first substrate to a second contact area of a second substrate, the second substrate having at least one reaction layer, said method comprising:
receiving the substrates into a plasma chamber or into a substrate chamber which is connected to a plasma chamber, the plasma chamber having at least first and second generators for respectively generating alternating current at different first and second frequencies (f₂₁, f₂₂), to produce the plasma,
forming a reservoir in a reservoir formation layer on the first contact area of the first substrate by applying a plasma, which has been produced in the plasma chamber, to the first contact area,
at least partially filling the reservoir with a first educt or a first group of educts,
contacting the first contact area of the first substrate with the second contact area of the second substrate to form a pre-bond interconnection, and
forming a permanent bond between the first and second contact area at least partially strengthened by the reaction of the first educt with a second educt which is contained in the at least one reaction layer of the second substrate.

2. The method as claimed in claim 1, wherein the first frequency (f₂₁) is between 1 Hz and 20 MHz.

3. The method as claimed in claim 1, wherein the second frequency (f₂₂) is between 1 Hz and 20 MHz.

4. The method as claimed in claim 1, wherein a voltage amplitude of the first and/or second electrode is between 1 V and 1000 V.

5. A method for bonding of a first contact area of a first substrate to a second contact area of a second substrate, the second substrate having a least one reaction layer, the method comprising:
receiving the first and second substrates into an inductively coupled plasma chamber,
forming a reservoir in a reservoir formation layer on the first contact area by exposing the first contact area to a plasma which has been produced by means of inductive coupling of, wherein a first generator generates alternating current at a first frequency (f₂₁) different from a second frequency (f₂₂) of an alternating current generated by a second generator during plasma production,
at least partially filling the reservoir with a first educt or a first group of educts,
contacting the first contact area with the second contact area to form a pre-bond interconnection,
forming a permanent bond between the first and second contact areas at least partially strengthened by the reaction of the first educt with a second educt which is contained in the at least one reaction layer of the second substrate.

6. The method as claimed in claim 5, wherein the first frequency (f₂₁) is between 0.001 kHz and 100000 kHz.

7. A device for bonding of a first contact area of a first substrate to a second contact area of a second substrate, the second substrate having a least one reaction layer, the device comprising:
a bonding chamber,
a first electrode and a second electrode located opposite the first electrode,
receiving means for receiving the substrates between the first electrode and the second electrode,
reservoir formation means for forming a reservoir in a reservoir formation layer on the first contact area by exposing the first contact area to a plasma which has been produced by means of capacitive coupling of the first and second electrodes and, wherein an alternating current at a first frequency (f₂₁) is applied to the first electrode during plasma production, wherein the first frequency is different from a second frequency (f₂₂) of an alternating current applied to the second electrode,
means for contacting the first contact area with the second contact area to form a pre-bond interconnection.

8. The device as claimed in claim 7, wherein the first and/or the second frequencies (f₂₁, f₂₂) are adjustable.

9. A device for bonding of a first contact area of a first substrate to a second contact area of a second substrate, the second substrate having a least one reaction layer, the device comprising:
a bonding chamber,
a coil,
receiving means for accommodating the substrates within the coil,
reservoir formation means for forming a reservoir in a reservoir formation layer on the first contact area by exposing the first contact area to a plasma which has been produced by means of capacitive coupling of the electrodes, wherein an alternating current of a first frequency (f₂₁) is applied to the first electrode during plasma production, wherein the first frequency is different from a second frequency (f₂₂) of an alternating current applied to the second electrode, and
means for contacting the first contact area with the second contact area to form a pre-bond interconnection.

10. The device as claimed in claim 9, wherein the first and/or the second frequencies (f₂₁, f₂₂) are adjustable.

11. The method as claimed in claim 1, wherein the method is carried out in a bonding chamber and the bonding chamber, at least in the formation of the reservoir, is exposed to a chamber pressure between 0.1 and 0.9 mbar.

12. The method as claimed in claim 11, wherein O₂ gas and/or N₂ gas and/or Ar gas predominates in the bonding chamber, at least when the reservoir is being formed.

13. A device for bonding of a first contact area of a first substrate to a second contact area of a second substrate, the second substrate having a least one reaction layer, the device comprising:
a plasma chamber for producing a plasma, the plasma chamber having at least two generators which can be respectively operated with different first and second frequencies (f₂₁, f₂₂), producing the plasma,
a bonding chamber connected to the plasma chamber,
reservoir formation means for forming a reservoir in a reservoir formation layer on the first contact area by exposing the first contact area to a plasma which has been produced in the plasma chamber,
means for contacting the first contact area with the second contact area to form a pre-bond interconnection.

14. The device as claimed in claim 13, wherein a closable opening is located between the plasma chamber and the bonding chamber.

15. The method as claimed in claim 1, wherein an ac voltage applied to a first electrode of said plasma chamber has the first frequency (f₂₁) in a frequency range between 1 Hz and 20 MHz.

16. The method as claimed in claim 1, wherein the first frequency (f₂₁) is between 0.001 kHz and 100000 kHz.

17. The method as claimed in claim 1, wherein the second frequency (f₂₂) is set in a frequency range between 0.001 kHz and 100000 kHz.

18. The method as claimed in claim 5, wherein the second frequency (f₂₂) is set in a frequency range between 0.001 kHz and 100000 kHz.

19. The method as claimed in claim 5, wherein the method is carried out in a bonding chamber and the bonding chamber, at least in the formation of the reservoir, is exposed to a chamber pressure between 0.1 and 0.9 mbar.

20. The method as claimed in claim 1, wherein O₂ gas and/or N₂ gas and/or Ar gas predominates in the bonding chamber, at least when the reservoir is being formed.

21. The method as claimed in claim 5, wherein O₂ gas and/or N₂ gas and/or Ar gas predominates in the bonding chamber, at least when the reservoir is being formed.

22. The method as claimed in claim 1, wherein a closable opening is located between the plasma chamber and the bonding chamber.
